(19) United States
(12) Patent Application Publication
(10) Pub. No.: US 2011/0270469 A1
(43) Pub. Date: Nov. 3, 2011

(54) UNIVERSAL MOUNTING SYSTEM FOR A HANDHELD ELECTRONIC DEVICE

(75) Inventors: Jayson K. Bopp, Fishers, IN (US); Andrew L. Nelson, Indianapolis, IN (US); Sarah L. Palmer, New Palestine, IN (US)

(73) Assignee: Raytheon Company, Waltham, MA (US)

(21) Appl. No.: 12/769,222

(22) Filed: Apr. 28, 2010

(51) Int. Cl. G05D 1/00; H05K 7/00

(52) U.S. Cl. 701/3; 361/679.01

(57) ABSTRACT

A universal mounting system for a handheld electronic device includes a handheld electronic device, a first mounting plate, and a second mounting plate. The handheld electronic device includes universal mounting members operable to mount to mounting plates. The first mounting plate includes first receiving members operable to detachably couple to the universal mounting members of the handheld electronic device. The first mounting plate also includes a fastener assembly operable to detachably couple the first mounting plate to a person. The second mounting plate includes second receiving members operable to detachably couple to the universal mounting members of the handheld electronic device. The second mounting plate also includes a connector assembly operable to attach the second mounting plate to a vehicle.

### GOVERNMENT RIGHTS

This invention was made with government support under government contract number N00019-05-G-0008, MV-22 Netted Weather Trade Study. The government may have certain rights in this invention.

### TECHNICAL FIELD OF THE DISCLOSURE

The present disclosure relates generally to handheld electronic devices, and, more particularly, to a universal mounting system for a handheld electronic device.

### BACKGROUND OF THE DISCLOSURE

Over time, the use of handheld electronic devices has increased. For example, pilots use electronic flight bags to obtain and transmit information regarding flights. Accordingly, the need for more convenient and portable handheld electronics devices also has increased. Devices and systems supporting the portability of handheld electronic devices, however, have proven inadequate in various respects.

### SUMMARY OF THE DISCLOSURE

In accordance with the teachings of the present disclosure, disadvantages and problems associated with previous devices and systems supporting the portability of handheld electronic devices can be reduced or eliminated by providing a universal mounting system for a handheld electronic device.

According to one embodiment of the present disclosure, a universal mounting system for a handheld electronic device includes a handheld electronic device, a first mounting plate, and a second mounting plate. The handheld electronic device includes universal mounting members operable to mount to mounting plates. The first mounting plate includes first receiving members operable to detachably couple to the universal mounting members of the handheld electronic device. The first mounting plate also includes a fastener assembly operable to detachably couple the first mounting plate to a person. The second mounting plate includes second receiving members operable to detachably couple to the universal mounting members of the handheld electronic device. The second mounting plate also includes a connector assembly operable to attach the second mounting plate to a vehicle.

Various embodiments of the present disclosure may provide various technical advantages. One advantage is the ability to provide a universal mounting system for a handheld electronics device. Another advantage may include increasing the ease at which a handheld electronics device may be moved from one mounted location to another. A handheld electronics device may be mounted to a person such that the hands of the person may be freed to conduct tasks other than carrying the handheld electronics device, while the same device may be removed from the person and attached to a vehicle. Thus, other technical advantages may include the ability to easily and quickly mount a handheld electronics device in a convenient location in a vehicle or on a person and then transition the device to another location. The ability to use the same hardware to attach the device in multiple locations may provide flexibility, reduced cost, increased performance, efficiencies, and other benefits.

Certain embodiments of the present disclosure may include none, some, or all of the above technical advantages. One or more other technical advantages may be readily apparent to one skilled in the art in view of the figures, descriptions, and claims of the present disclosure.

### BRIEF DESCRIPTION OF THE DRAWINGS

For a more complete understanding of the present invention and its features and advantages, reference is now made to the following description, taken in conjunction with the accompanying drawings, in which:

FIG. 1A is a front perspective view of an exemplary embodiment of a universal mounting system for a handheld electronic device mounted in a vehicle;

FIG. 1B is an enlarged front perspective view of an exemplary embodiment of a universal mounting system for a handheld electronic device mounted in a vehicle;

FIG. 1C is a front perspective view of an exemplary handheld electronics device including universal mounting members of a universal mounting system;

FIG. 1D is a rear perspective view of an exemplary handheld electronics device including universal mounting members of a universal mounting system;

FIG. 1E is a front perspective view of an exemplary vehicle mounting plate;

FIG. 2A is a front perspective view of an exemplary embodiment of a universal mounting system for a handheld electronic device mounted on a person;

FIG. 2B is a front perspective view of an exemplary universal mounting system including an exemplary leg mounting plate;

FIG. 3A is an illustration demonstrating an initial loading position of a universal mounting system as a handheld electronics device is being loaded onto an exemplary mounting plate;

FIG. 3B is an illustration demonstrating an intermediary position of a universal mounting system as a handheld electronic device is transitioned from an initial loading position to an ending locked position on an exemplary mounting plate; and

FIG. 3C is an illustration demonstrating an ending locked position of a universal mounting system on an exemplary mounting plate.

### DETAILED DESCRIPTION OF THE DISCLOSURE

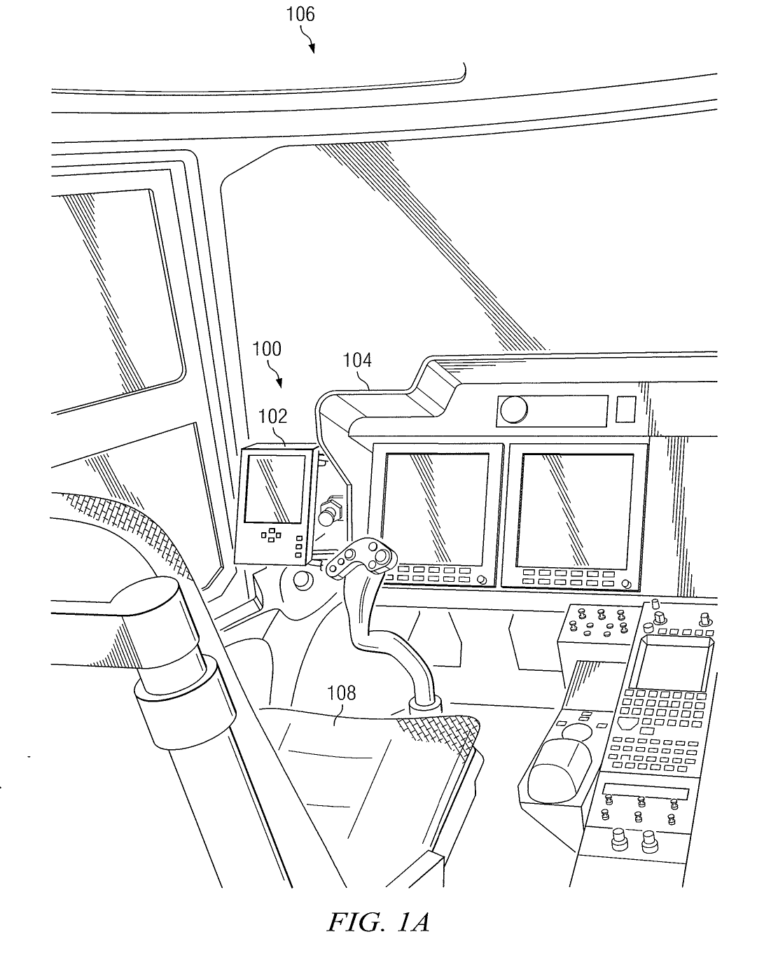

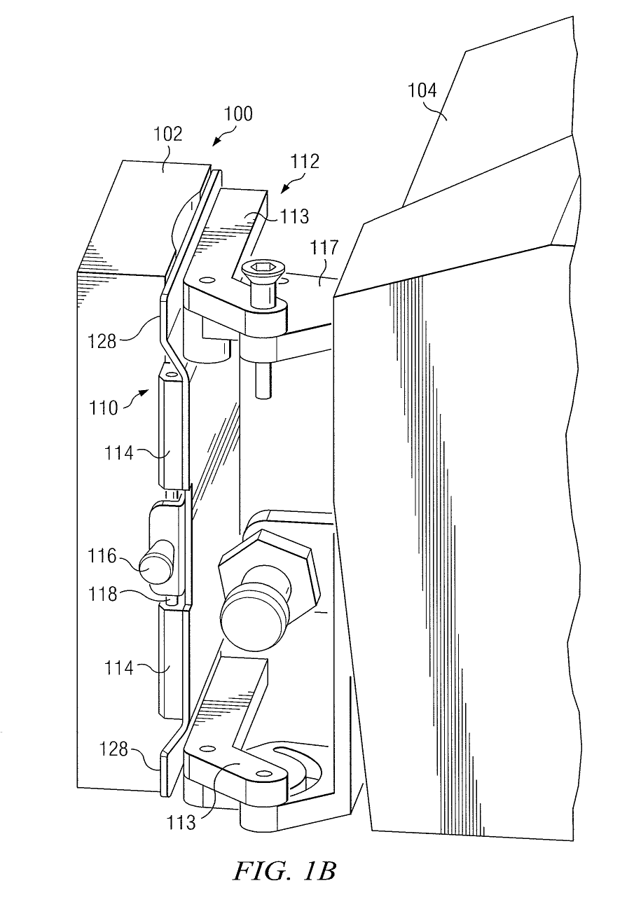

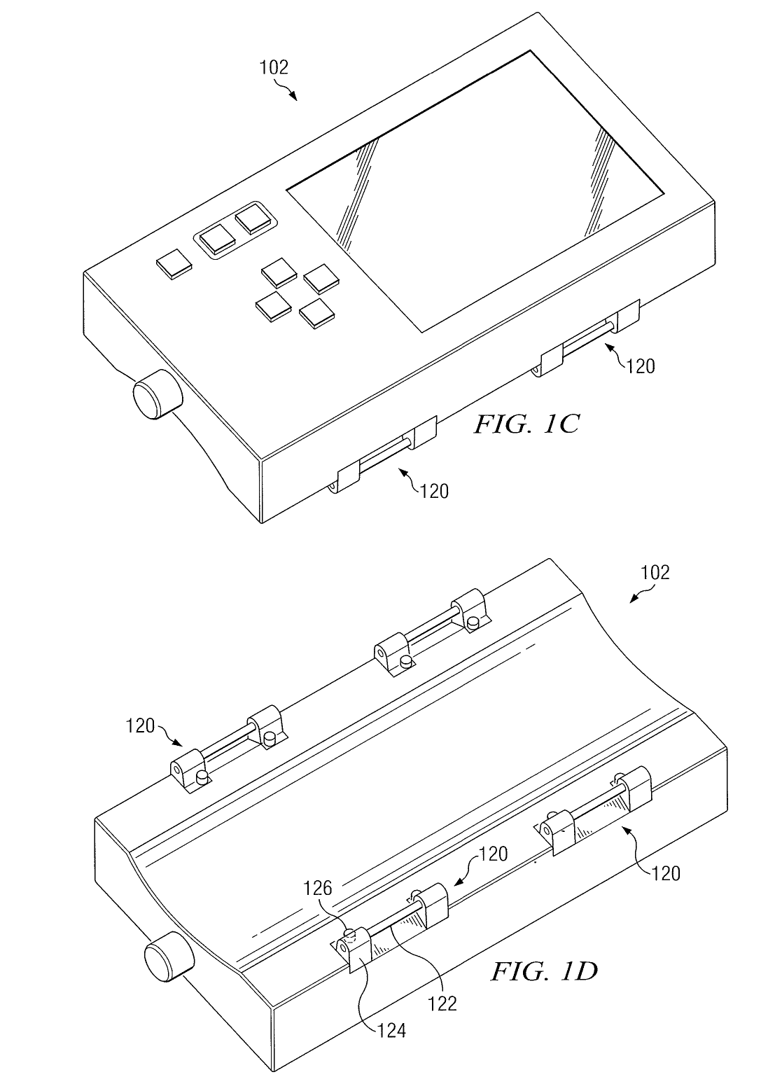

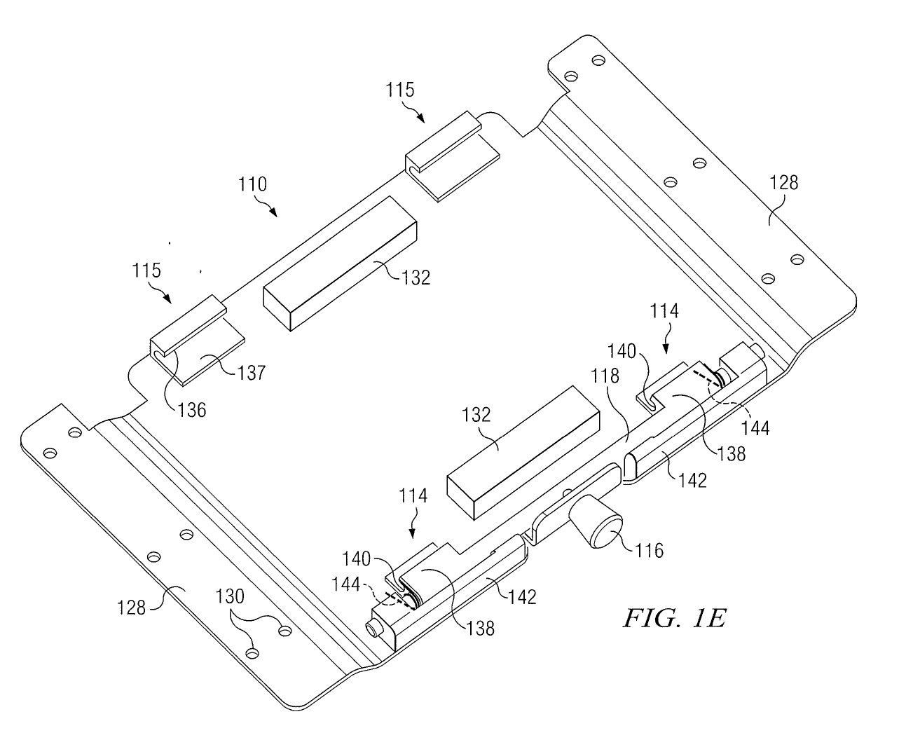

FIG. 1A is a front perspective view of an exemplary embodiment of a universal mounting system for a handheld electronic device mounted in a vehicle. As illustrated, universal mounting system 100 includes an electronic flight bag 102 mounted to a console 104 of an aircraft cockpit 106. The universal mounting system 100 may be configured in aircraft cockpit 106 such that electronic flight bag 102 faces the seat 108 of cockpit 106.

Generally, electronic flight bags 102 are computing devices that perform functionality associated with operation of an aircraft. In many cases, electronic flight bags 102 may include functionality that is useful to pilots during flight. For example, electronic flight bags 102 may include navigational charts to aid users with the development of flight plans. An electronic flight bag may include weather data, radar data, sensor data, and/or a real-time GPS navigational map indicating the instantaneous position of the aircraft. These electronic flight bags 102 may also include various tools for calculating other operational parameters of the aircraft's flight including the minimum amount of fuel needed, takeoff speed, and/or specific routes to be taken.

Electronic flight bags 102 are often housed in relatively small tablet-sized housings that may be easily carried by pilots of aircraft and may include touch screens for entry of information. In some circumstances, it may be desirable to mount an electronic flight bag to console 104 of aircraft cockpit 106 such that the pilot may easily view the screen of electronic flight bag 102 during flight. In other circumstances, it may be desirable to mount the electronic flight bag 102 to the leg of the pilot. These circumstances may depend on a pilot's flight schedule or other non-flight obligations. For example, a pilot may desire to mount electronic flight bag 102 to console 104 during relatively long flights and/or mount electronic flight bag 102 to the pilot's leg during relatively shorter flights and/or ground operations. Accordingly, a universal mounting system, such as universal mounting system 100 and/or universal mounting system 200, discussed below, provides the capability to detachably mount an electronic flight bag 102 to a vehicle, such as an aircraft, and/or to an appendage of a person, such as a pilot's leg.

It should be understood that while electronic flight bag 102 is depicted in a particular arrangement relative to console 104, any location and configuration is appropriate in aircraft cockpit 106 that allows viewing of information displayed on electronic flight bag 102 by a pilot from seat 108. It should additionally be understood that while a particular embodiment of the present disclosure is described with respect to electronic flight bags, aircraft cockpits, and pilots, the scope of the present disclosure encompasses a universal mounting system for any number and type of handheld electronics devices, vehicles, and persons.

FIG. 1B is an enlarged front perspective view of an exemplary embodiment of universal mounting system 100. Universal mounting system 100 may mount electronic flight bag 102 to console 104 using a vehicle mounting plate 110 and a cockpit mounting assembly 112. Vehicle mounting plate 110 includes receiving members 114, a spring loaded plunger 116, and a rod 118. Generally, electronic flight bag 102 is detachably coupled to receiving members 114 and locked into vehicle mounting plate 110 with spring loaded plunger 116. Receiving members 114 are operable to rotate on rod 118 from an unlocked position to a locked position. In some embodiments, receiving members 114 may form a portion of rod 118. It should be understood, however, that while receiving members 114, spring loaded plunger 116, and rod 118 are illustrated as positioned along one edge of vehicle mounting plate 110, that these elements may be positioned along any appropriate edge of vehicle mounting plate 110, such as the edge opposite to the one illustrated.

Vehicle mounting plate 110 represents any combination of structure and materials operable to form a substantially planar surface appropriate for maintaining electronic flight bag 102 in a substantially locked position relative to the surface of vehicle mounting plate 110. Vehicle mounting plate 110 may include connector flanges 128 operable to attach vehicle mounting plate 110 to cockpit mounting assembly 112. Vehicle mounting plate 110 may include receiving members 114 operable to detachably couple electronic flight bag 102 to vehicle mounting plate 110.

Cockpit mounting assembly 112 represents any combination of structure and materials operable to attach vehicle mounting plate 110 to console 104 or any other appropriate interior surface of an aircraft and/or other vehicle. In the illustrated embodiment, cockpit mounting assembly 112 includes two arms 113 rotatably coupled to a pivot point on a base unit 117 that is attached to console 104. Connector flanges 128 of vehicle mounting plate 110 may be attached to arms 113 of cockpit mounting assembly 112. For example, one or more bolts, screws, rivets, or other connectors may be arranged in a pattern along arms 113 that pass substantially through connector flanges 128 and into arms 113. In the alternative or in addition, vehicle mounting plate 110 may be welded, glued, or otherwise fixed to arms 113 of cockpit mounting assembly 112.

Receiving members 114 represent any combination of structure and materials operable to receive mounting members attached to electronic flight bag 102. Receiving members 114 will be discussed in greater detail below.

Spring loaded plunger 116 represents any combination of structure and materials operable to lock electronic flight bag 102 into a locked position on vehicle mounting plate 110. Spring loaded plunger 116 will be discussed in greater detail below.

Accordingly, Electronic flight bag 102 may detachably couple to vehicle mounting plate 110, and vehicle mounting plate 110 may be attached to cockpit mounting assembly 112. Cockpit mounting assembly 112 may be operable to rotate about a pivot point such that electronic flight bag 102 may be stored in a stowable position relative to console 104 and/or in a position where the display of electronic flight bag 102 faces seat 108 of aircraft cockpit 106 for viewing by a pilot.

FIGS. 1C and 1D are respectively a front and a rear perspective view of an exemplary electronic flight bag 102 that includes universal mounting members 120 of a universal mounting system. As illustrated, universal mounting members 120 include universal mounting pins 122, supports 124, and fasteners 126.

Universal mounting members 120 represent any combination of structure and materials operable to attach to a surface of electronic flight bag 102 and to detachably couple to receiving members of a vehicle mounting plate, a leg mounting plate, or other appropriate mounting surfaces. In the illustrated embodiment, universal mounting members 120 are generally arranged along two edges of electronic flight bag 102, such that two universal mounting members 120 are arranged along each of the two edges. Any appropriate configuration, however, may be used. As illustrated, universal mounting members 120 may be attached to a rear surface of electronic flight bag 102 using fasteners 126. In some embodiments, universal mounting members 120 may form a part of a separate case or shell that encloses a handheld electronics device such as electronic flight bag 102.

Each of universal mounting pins 122 represents any combination of structure and material operable to detachably couple electronic flight bag 102 to receiving members of a vehicle mounting plate, a leg mounting plate, or other appropriate mounting surface. Each of universal mounting pins 122 may represent a substantially smooth and cylindrical pin operable to slide into a clip that forms a portion of each receiving member of a given mounting plate. Each end of universal mounting pins 122 may be attached to a support structure 124 such that a space is formed between the universal mounting pin 122 and the rear surface of the electronic flight bag 102. Accordingly, the lower portion of each receiving member may slide between universal mounting pin 122 and the surface of electronic flight bag 102.

Fasteners 126 include any structure and material appropriate to attach universal mounting members 120 to a surface of electronic flight bag 102. For example, fasteners 126 may include screws, bolts, rivets, glue, epoxy, and/or welds.

FIG. 1E is a front perspective view of an exemplary vehicle mounting plate 110. Vehicle mounting plate 110 includes receiving members 114, receiving members 115, spring loaded plunger 116, connector flanges 128, fastener holes 130, and shock absorbers 132. Receiving members 114 may include rod 118, rotatable arms 138, clips 140, base supports 142, and springs 144. Receiving members 115 may include clips 136 and clip supports 137.

Receiving members 114 represent any combination of structure and materials operable to detachably couple electronic flight bag 102 to the outer surface of vehicle mounting plate 110. In the illustrated embodiment, receiving members 114 are located along an edge of vehicle mounting plate 110. Receiving members 114 may include a rotatable arm 138 that rotates on rod 118. A portion of rotatable arm 138 may form clips 140. Each of clips 140 may form a substantially smooth inner surface of generally similar shape and radius to a portion of the outer surface of universal mounting pins 122 discussed above. In some embodiments, rotatable arm 138 and clips 140 may be formed on and/or attached to rod 118. Spring 144 may be configured between rotatable arm 138 and the surface of vehicle mounting plate 110. Accordingly, spring 144 may be compressed as rotatable arm 138 rotates on rod 118 toward the surface of vehicle mounting plate 110. Rotatable arm 138 may spring away from vehicle mounting plate 110 when released by spring loaded plunger 116. While springs 144 are depicted in a particular configuration, however, it should be understood that springs 144 may be located and configured in any appropriate manner such that rotatable arm 138 has a desired springing action.

Receiving members 115 represent any combination of structure and materials operable to detachably couple electronic flight bag 102 to the outer surface of vehicle mounting plate 110. Receiving members 115 may include a clip 136 and clip support 137. Each of clips 136 may form a substantially smooth inner surface of generally similar shape and radius to a portion of the outer surface of universal mounting pins 122 discussed above.

Spring loaded plunger 116 represents any combination of springs, coils, pins, knobs, or other appropriate structure and materials operable to lock electronic flight bag 102 onto vehicle mounting plate 110 and release electronic flight bag 102 from a locked position to an unlocked position. Spring loaded plunger 116 may be operable to lock electronic flight bag 102 into a locked position when clips 136 and clips 140 receive universal mounting pins 122. Spring loaded plunger 116 also may be operable to release electronic flight bag 102 from a locked position into an unlocked position by engaging the spring loaded plunger 116. For example, spring loaded plunger 116 may be operable to lock rod 118 into position to prevent rod 118 from rotating.

Rod 118 represents any combination of structure and materials operable to rotate with respect to base supports 142. In some embodiments, a portion of rod 118 may form rotatable arms 138 and clips 140. Accordingly, clips 140 along with rotatable arms 138 may rotate as rod 118 rotates with respect to base supports 142.

Connector flanges 128 represent any combination of structure and materials operable to form a connecter assembly comprising flanges formed along two edges of vehicle mounting plate 110. Connector flanges 128 faun a number of fastener holes 130. Fastener holes 130 represent a series of threaded and/or unthreaded holes of any appropriate size and arrangement useful to attach vehicle mounting plate 110 to cockpit mounting assembly 112 using a series of fasteners of appropriate thread size and/or other dimension to pass partially through fastener holes 130. While not shown, fasteners may include screws, bolts, or other fastening devices operable to fasten vehicle mounting plate 110 to cockpit mounting assembly 112. It should be understood, however, that while connector flanges 128 are depicted as formed as part of vehicle mounting plate 110, that any appropriate connector assembly may be used to attach vehicle mounting plate 110 to an interior surface of a vehicle.

Shock absorbing pads 132 represent any appropriate materials operable to adsorb shock caused by the movement of a vehicle that would otherwise cause electronic flight bag 102 to move in an undesired manner relative to vehicle mounting plate 110. For example, shock absorbing pads 132 may represent a substance made of rubber, gel, foam, or other compressible material. Shock absorbing pads 132 may form any shape operable to compress against the rear surface of electronic flight bag 102 when electronic flight bag 102 is locked into a mounted position on vehicle mounting plate 110.

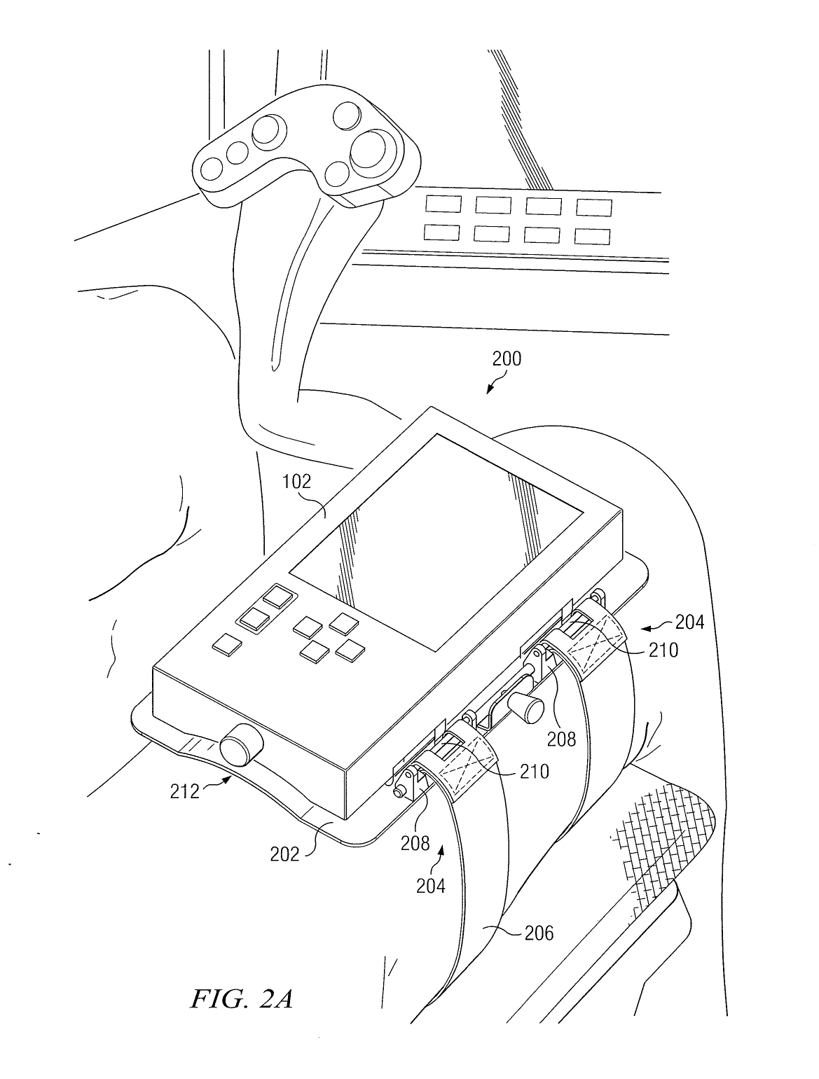

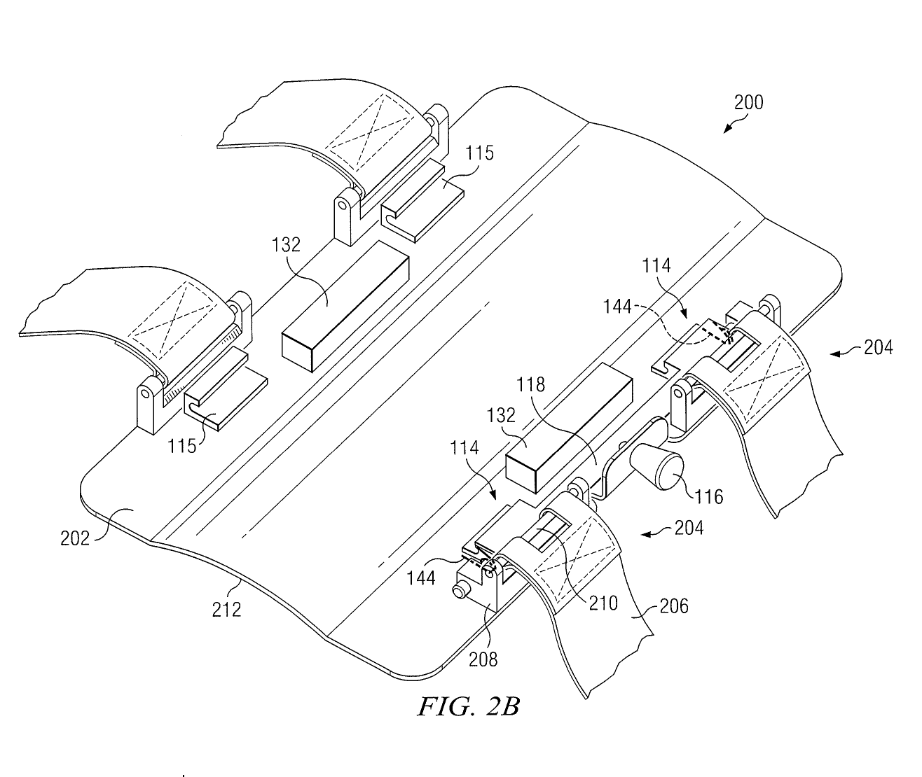

FIG. 2A is a front perspective view of an exemplary embodiment of a universal mounting system 200 for a handheld electronic device mounted on a person. Universal mounting system 200 mounts electronic flight bag 102 to a leg of a person, such as a pilot, using a leg mounting plate 202 and leg fastener assemblies 204. Leg mounting plate 202 may form a contour 212. In general, leg mounting plate 202 detachably couples to the appendage of a person using leg fastener assemblies 204. Electronic flight bag 102, in turn, may detachably couple to leg mounting plate 202.

Leg fastener assemblies 204 represent any combination of structure and materials operable to detachably couple leg mounting plate 202 to an appendage of a person, such as the leg of a pilot. Leg fastener assemblies 204 may include belt straps 206, holder supports 208, and holder pins 210.

Belt straps 206 represent any combination of structure and materials operable to detachably surround the appendage of a person. For example, one or more detachable and/or releasable straps may surround a human leg. Belt strap 206 may be formed from any appropriate type of flexible material, such as cloth, plastic, canvas, nylon, and/or carbon fiber. Additionally or alternatively, belt straps 206 may be formed of woven threads and/or may be formed of a solid material. In some embodiments, belt straps 206 may include an elastic portion and/or a tightening mechanism operable to tighten and/or vary the length of belt straps 206 according to the varying dimensions of pilots' legs. Belt straps 206 may include a detachable mechanism such as a clip, bracket, or buckle that detachably couples ends of belt straps 206. It should be noted, however, that while belt straps 206 are illustrated, any appropriate fastener assemblies may be used to detachably couple leg mounting plate 202 to a person, such as Velcro or other appropriate detachable material.

Holder supports 208 and holder pins 210 represent any combination of structures and materials operable to attach belt straps 206 to leg mounting plate 202. As illustrated, each of holder supports 208 form a support structure for a holder pin 210. Each end of belt strap 206 may loop around one of holder pins 210 such that each end of belt strap 206 may be affixed to another portion of belt strap 206. Accordingly, belt strap 206 may be attached to holder pins 210. It should be noted, however, that any appropriate attachment assembly may be used to attach belt straps 206 to leg mounting plate 202. In some embodiments, holder supports 208 may include a releasable mechanism that allows holder supports 208 and/or holder pins 210 to detachably couple to the surface of leg mounting plate 202.

Contour 212 represents a portion of leg mounting plate 202 that forms a grooved surface running along a center axis of leg mounting plate 202. Contour 212 may be formed to allow leg mounting plate 202 to substantially conform to the shape of a human appendage, such as a leg. It should be understood, however, that while illustrated as configured on the thigh portion of a pilot's leg, the scope of the present disclosure encompasses a universal mounting system that may be adapted to any appendage, such as a calf, arm, wrist, or torso. Alternatively or in addition, universal mounting system 200 may be desirable for use by persons other than pilots, such as law enforcement officers, entertainers, or other electronics consumers.

FIG. 2B is a front perspective view of universal mounting system 200 including an exemplary leg mounting plate 202. Leg mounting plate 202 includes receiving members 114, receiving members 115, spring loaded plunger 116, rod 118, shock absorbers 132, and springs 144, examples of which have been previously described. Leg mounting plate 202 also includes leg fastener assemblies 204, belt straps 206, holder supports 208, holder pins 210, and contour 212, examples of which have also been previously described. Accordingly, receiving members 114 and 115 of leg mounting plate 202 may receive universal mounting pins 122 of electronic flight bag 102. Thus, electronic flight bag 102 may detachably couple to leg mounting plate 202 in a similar manner as described with respect to vehicle mounting plate 110. Similarly, leg fastener assemblies 204 along with belt straps 206 may allow leg mounting plate 202 to detachably couple to a leg of a pilot.

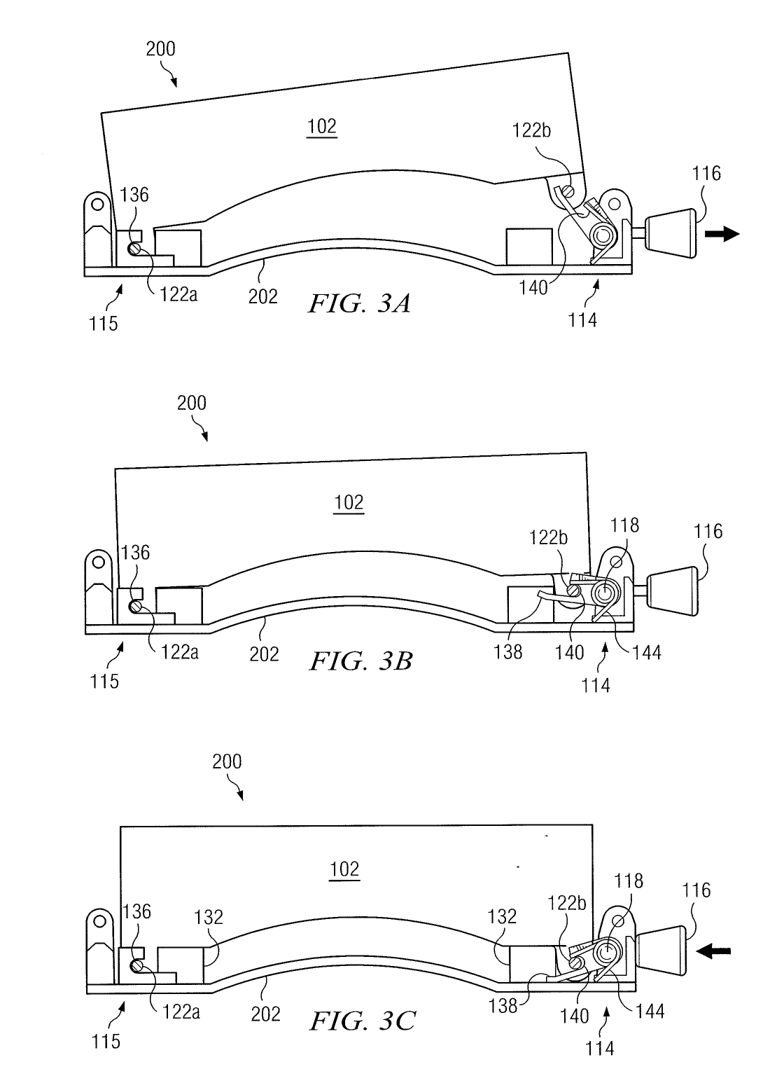

FIG. 3A is an illustration demonstrating an initial loading position of a universal mounting system 200 as a handheld electronics device is being loaded onto an exemplary mounting plate. As illustrated, electronic flight bag 102 is positioned in an unlocked position on leg mounting plate 202 such that clips 136 of receiving members 115 receive universal mounting pins 122a of electronic flight bag 102. Spring loaded plunger 116 may be operable to be pulled outward from leg mounting plate 202 along an axis perpendicular to an edge of the leg mounting plate 202, as shown by the directional arrow.

As illustrated, universal mounting pins 122a on one side of electronic flight bag 102 may slide into clips 136 of receiving members 115. Electronic flight bag 102 then rotates on universal mounting pins 122a in clips 136. Accordingly, universal mounting pins 122b may move toward clips 140 of receiving members 114.

FIG. 3B is an illustration demonstrating an intermediary position of a universal mounting system 200 as a handheld electronic device is transitioned from an initial loading position to an ending locked position on an exemplary mounting plate. As electronic flight bag 102 rotates in clips 136 of receiving members 115 and universal mounting pins 122b are received into clips 140 of receiving members 114, rotatable arm 138 may begin to rotate on rod 118. As rotatable arm 138 rotates toward the surface of leg mounting plate 202, spring 144 compresses. Rotatable arm 138 rotates until reaching a position at which spring loaded plunger 116 may lock rotatable arm 138 into place.

FIG. 3C is an illustration demonstrating an ending locked position of a universal mounting system 200 on an exemplary mounting plate. As illustrated, universal mounting pins 122a and 122b of electronic flight bag 102 are respectively locked into clips 140 of receiving members 114 and clips 136 of receiving members 115 of leg mounting plate 202. In the locked position, shock absorbing pads 132 may compress against the rear surface of the electronic flight bag 102 such that the electronic flight bag may be secured into position and unwanted movement of electronic flight bag 102 with respect to leg mounting plate 202 may be reduced and/or eliminated. Once the locked position of electronic flight bag 102 has been reached, spring loaded plunger 116 may spring back towards the edge of leg mounting plate 202 to prevent rod 118 from rotating and thereby lock electronic flight bag 102 onto leg mounting plate 202.

In the locked position, spring 144 is compressed. Spring loaded plunger 116 may be engaged to release electronic flight bag 102 from leg mounting plate 202 by pulling it away from the edge of electronic flight bag 102. Accordingly, energy stored in spring 144 will be released, causing rotatable arm 138 to rotate and clips 140 to rotatably spring away from the surface of leg mounting plate 202 on rod 118. Thus, electronic flight bag 102 may be decoupled from leg mounting plate 202.

It should be understood that while an exemplary leg mounting plate 202 is shown in the preceding illustrations, an electronic handheld device may similarly be loaded on any appropriate mounting plate, such as vehicle mounting plate 110. Accordingly, while the preceding illustrations depict an initial loading position, an intermediary position, and an ending locked position of universal mounting system 200, a handheld electronic device may similarly mount to any appropriate universal mounting system, such as universal mounting system 100.

Although the present invention has been described with several embodiments, a myriad of changes, variations, alterations, transformations, and modifications may be suggested to one skilled in the art and it is intended that the present invention encompass such changes, variations, alterations, transformations, and modifications as fall within the scope of the appended claims.

What is claimed is:

1. A universal mounting system for a handheld electronic device, comprising:
a handheld electronic device including a plurality of universal mounting members operable to mount to a plurality of mounting plates;
a first mounting plate including a plurality of first receiving members operable to detachably couple to the universal mounting members of the handheld electronic device, the first mounting plate further including a fastener assembly operable to detachably couple the first mounting plate to a person; and
a second mounting plate including a plurality of second receiving members operable to detachably couple to the universal mounting members of the handheld electronic device, the second mounting plate further including a connector assembly operable to attach the second mounting plate to a vehicle.

2. The universal mounting system of claim 1, wherein each of the universal mounting members includes a universal mounting pin, and each of the first receiving members and each of the second receiving members includes a clip operable to receive the universal mounting pin.

3. The universal mounting system of claim 2, wherein at least one of the clips of the first receiving members forms a portion of an arm rotatably coupled to a support attached to the first mounting plate, wherein the aim is operable to rotate from an unlocked position to a locked position, thereby compressing a spring coupled to the arm and to the support.

4. The universal mounting system of claim 3, wherein the first mounting plate further includes a spring loaded plunger operable to lock the handheld electronic device into the locked position.

5. The universal mounting system of claim 2, wherein at least one of the clips of the second receiving members forms a portion of an arm rotatably coupled to a support attached to the second mounting plate, wherein the arm is operable to rotate from an unlocked position to a locked position, thereby compressing a spring coupled to the arm and to the support; and
wherein the second mounting plate further includes a spring loaded plunger operable to lock the handheld electronic device into the locked position.

6. The universal mounting system of claim 1, wherein each of the plurality of mounting plates further includes a plurality of shock absorbing pads, wherein the plurality of shock absorbing pads are operable to compress against a surface of the handheld electronic device when the handheld electronic device is in a locked position.

7. The universal mounting system of claim 1, wherein the fastener assembly includes a strap coupled to a holder attached to the first mounting plate, wherein the strap is operable to detachably surround an appendage of the person.

8. The universal mounting system of claim 1, wherein at least one surface of a base of the first mounting plate forms a groove substantially similar to a contour of an appendage of the person.

9. The universal mounting system of claim 1, wherein the connecter assembly includes a flange formed from a base of the second mounting plate, the flange forming a plurality of holes, wherein each of a plurality of fasteners is operable to at least partially pass through one of the holes to attach the second mounting plate to an interior surface of the vehicle.

10. The universal mounting system of claim 1, wherein:
the handheld electronic device is an electronic flight bag;
the person is a pilot;
the fastener assembly of the first mounting plate detachably couples the first mounting plate to a leg of the pilot;
the vehicle is an aircraft that includes a cockpit;
the connector assembly of the second mounting plate attaches the second mounting plate to a console in the cockpit of the aircraft;
the universal mounting members of the electronic flight bag are operable to detachably couple to the first receiving members of the first mounting plate when the first mounting plate is detachably coupled to the leg of the pilot; and
the universal mounting members of the electronic flight bag are operable to detachably couple to the second receiving members of the second mounting plate when the second mounting plate is attached to the console in the cockpit of the aircraft.

11. A handheld electronic device comprising:
a plurality of universal mounting members attached to a surface of a handheld electronic device, wherein the plurality of universal mounting members are operable to mount to a plurality of mounting plates, wherein the plurality of mounting plates include a first mounting plate and a second mounting plate;
wherein the first mounting plate includes a plurality of first receiving members operable to detachably couple to the universal mounting members of the handheld electronic device, the first mounting plate further including a fastener assembly operable to detachably couple the first mounting plate to a person; and
wherein the second mounting plate includes a plurality of second receiving members operable to detachably couple to the universal mounting members of the handheld electronic device, the second mounting plate further including a connector assembly operable to attach the second mounting plate to a vehicle.

12. The handheld electronic device of claim 11, wherein each of the universal mounting members includes a universal mounting pin, and each of the first receiving members and each of the second receiving members includes a clip operable to receive the universal mounting pin.

13. The handheld electronic device of claim 12, wherein at least one of the clips of the first receiving members forms a portion of an arm rotatably coupled to a support attached to the first mounting plate, wherein the aim is operable to rotate from an unlocked position to a locked position, thereby compressing a spring coupled to the arm and to the support.

14. The handheld electronic device of claim 13, wherein the first mounting plate further includes a spring loaded plunger operable to lock the handheld electronic device into the locked position.

15. The handheld electronic device of claim 11, wherein each of the plurality of mounting plates further includes a plurality of shock absorbing pads, wherein the plurality of shock absorbing pads are operable to compress against the surface of the handheld electronic device when the handheld electronic device is in a locked position.

16. The handheld electronic device of claim 11, wherein the fastener assembly includes a strap coupled to a holder attached to the first mounting plate, wherein the strap is operable to detachably surround an appendage of the person.

17. The handheld electronic device of claim 11, wherein at least one surface of a base of the first mounting plate forms a groove substantially similar to a contour of an appendage of the person.

18. The handheld electronic device of claim 11, wherein the connecter assembly includes a flange formed from a base of the second mounting plate, the flange forming a plurality of holes, wherein each of a plurality of fasteners is operable to at least partially pass through one of the holes to attach the second mounting plate to an interior surface of the vehicle.

19. The handheld electronic device of claim 11, wherein:
the handheld electronic device is an electronic flight bag;
the person is a pilot;
the fastener assembly of the first mounting plate detachably couples the first mounting plate to a leg of the pilot;
the vehicle is an aircraft that includes a cockpit;
the connector assembly of the second mounting plate attaches the second mounting plate to a console in the cockpit of the aircraft;
the universal mounting members of the electronic flight bag are operable to detachably couple to the first receiving members of the first mounting plate when the first mounting plate is detachably coupled to the leg of the pilot; and
the universal mounting members of the electronic flight bag are operable to detachably couple to the second receiving members of the second mounting plate when the second mounting plate is attached to the console in the cockpit of the aircraft.

20. A universal mounting system for an electronic flight bag, comprising:
an electronic flight bag including a plurality of universal mounting members operable to mount to a plurality of mounting plates, wherein each of the universal mounting members includes a universal mounting pin;
a first mounting plate including a plurality of first receiving members operable to detachably couple to the universal mounting members of the electronic flight bag, wherein:
each of the first receiving members includes a first clip operable to receive the universal mounting pin, at least one of the first clips of the first receiving members forms a first portion of a first aim rotatably coupled to a first support attached to the first mounting plate, the first arm is operable to rotate from a first unlocked position to a first locked position, thereby compressing a first spring coupled to the first arm and to the first support, and the first mounting plate further includes a first spring loaded plunger operable to lock the electronic flight bag into the first locked position; and
the first mounting plate further includes a fastener assembly operable to detachably couple the first mounting plate to a pilot, the fastener assembly includes a strap coupled to a holder attached to the first mounting plate, the strap is operable to detachably surround a leg of the pilot, and at least one surface of a base of the first mounting plate forms a groove substantially similar to a contour of the leg of the pilot; and
a second mounting plate including a plurality of second receiving members operable to detachably couple to the universal mounting members of the electronic flight bag, wherein:
each of the second receiving members include a second clip operable to receive the universal mounting pin, at least one of the second clips of the second receiving members forms a second portion of a second arm rotatably coupled to a second support attached to the second mounting plate, the second arm is operable to rotate from a second unlocked position to a second locked position, thereby compressing a second spring coupled to the second arm and to the second support, and the second mounting plate further includes a second spring loaded plunger operable to lock the electronic flight bag into the second locked position; and
the second mounting plate further includes a connector assembly operable to attach the second mounting plate to an aircraft that includes a cockpit, the connecter assembly includes a flange formed from a base of the second mounting plate, the flange forming a plurality of holes, and each of a plurality of fasteners is operable to at least partially pass through one of the holes to attach the second mounting plate to a console in the cockpit of the aircraft.
